(19) United States
(12) Patent Application Publication
(10) Pub. No.: US 2017/0352562 A1
(43) Pub. Date: Dec. 7, 2017

(54) DODECADON TRANSFER CHAMBER AND PROCESSING SYSTEM HAVING THE SAME

(71) Applicant: Applied Materials, Inc., Santa Clara, CA (US)

(72) Inventors: Shinichi KURITA, San Jose, CA (US); Makoto INAGAWA, Palo Alto, CA (US); Hanzheng H. LIN, San Jose, CA (US); Takayuki MATSUMOTO, Cupertino, CA (US); Suhail ANWAR, Saratoga, CA (US)

(21) Appl. No.: 15/171,783

(22) Filed: Jun. 2, 2016

(51) Int. Cl. H01L 21/67; C23C 16/04; H01L 21/02; C23C 16/34; C23C 16/40; H01J 37/32; H01L 21/677; C23C 16/30

(52) U.S. Cl. CPC H01L 21/67167; H01L 21/67742; C23C 16/042; H01L 21/67201; H01L 21/67196; H01L 21/67207; C23C 16/308; C23C 16/345; C23C 16/402; H01J 37/32743; H01J 37/32788; H01L 21/02271; H01L 21/0217; H01L 21/02164; H01L 21/0214; H01J 37/32899; H01J 37/32816; H01J 37/32082; H01J 2237/327; H01J 2237/3321; H01J 2237/3326; H01L 21/02274; H01L 21/0228

(57) ABSTRACT

A transfer chamber for a processing system suitable for processing a plurality of substrates and a method of using the same is provided. The transfer chamber includes a lid, a bottom disposed opposite the lid, a plurality of sidewalls sealingly coupling the lid to the bottom and defining an internal volume, wherein the plurality of sidewalls form the faces of a dodecagon. An opening is formed in each of the faces, wherein the opening is configured for a substrate to pass therethrough. A transfer robot is disposed in the internal volume, wherein the transfer robot has effectors configured to support the substrate through one opening to another opening.

### BACKGROUND

### Field

Embodiments of the disclosure generally relate to a vacuum processing system for vacuum processing large area substrates (e.g., LCD, OLED, and other types of flat panel displays, solar panels and the like), and more specifically to a transfer chamber of the processing system.

### Description of the Related Art

Large area substrates are used to produce flat panel displays (i.e., LCD, OLED, and other types of flat panel displays), solar panels, and the like. Large area substrates are generally processed in one or more vacuum processing chambers, where various deposition, etching, plasma processing and other circuit and/or device fabrication processes are performed. The vacuum processing chambers are typically coupled by a common vacuum transfer chamber that contains a robot that transfers the substrates between the different vacuum processing chambers. The assembly of the transfer chamber and other chambers connected to the transfer chamber (e.g., the processing chambers) is often referred to as a processing system.

During fabrication of flat panel displays, the substrate is moved between various processing chambers while under a vacuum condition. Since deposition of films on the substrate may require a significant amount of time, multiple processing systems are often utilized to achieve requisite substrate processing throughput required to meet production goals. However, using multiple processing systems consumes valuable factory floor space, while simply speeding up deposition processes often lead to unsatisfactory film quality.

Thus, there is need for an improved processing system.

### SUMMARY

Embodiments of the disclosure generally relate to vacuum processing large area substrates. In one embodiment, a transfer chamber for a processing system suitable for processing a plurality of substrates and a method of using the same is provided. The transfer chamber includes a lid, a bottom disposed opposite the lid, a plurality of sidewalls sealingly coupling the lid to the bottom and defining an internal volume, wherein the plurality of sidewalls form the faces of a dodecagon. An opening is formed in each of the faces, wherein the opening is configured for a substrate to pass therethrough. A transfer robot is disposed in the internal volume, wherein the transfer robot has effectors configured to support the substrate through one opening to another opening.

In another embodiment, a processing system for fabricating a plurality of substrates is provided. The system includes a transfer chamber. The transfer chamber includes a lid, a bottom disposed opposite the lid, a plurality of sidewalls sealingly coupling the lid to the bottom and defining an internal volume, wherein the plurality of sidewalls form the faces of a dodecagon. An opening is formed in each of the faces, wherein the opening is configured for a substrate to pass therethrough. A transfer robot is disposed in the internal volume. A load lock chamber is coupled to the transfer chamber and has an opening, wherein the opening is aligned with and sealing attached to one of the openings in the transfer chamber. A mask chamber is coupled to the transfer chamber and has an opening, wherein the opening is aligned with and sealing attached to another of the openings in the transfer chamber. A plurality of processing chambers are coupled to the transfer chamber and have openings, wherein the openings are aligned with and sealing attached to one of the openings in the transfer chamber respectively. The transfer robot has effectors configured to support and move a substrate or mask from one of the chambers attached to the transfer chamber to another.

In another embodiment, a method of processing a plurality of substrates is provided. The method includes placing transferring seven substrates to a transfer chamber. Depositing a silicon containing film on the seven substrates in seven separate processing chambers directly attached to the transfer chamber. The method concludes by transferring the seven substrates out of the transfer chamber after one film deposition.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a top cross-sectional view of a processing system for vacuum processing a plurality of substrates having a transfer chamber, according to one embodiment.

FIG. 2 is a side cross-sectional view of a load lock chamber shown in the processing system in FIG. 1, according to one embodiment.

FIG. 3A is a top plan view of the transfer chamber of FIG. 1, according to one embodiment.

FIG. 3B is a side plan view of the transfer chamber of FIG. 1, according to one embodiment.

FIG. 4 is a side cross-sectional view of a robot for use in the transfer chamber of FIG. 1, according to one embodiment.

FIG. 5 is a side cross-sectional view of a buffer chamber of FIG. 1, according to one embodiment.

FIG. 6 is a side cross-sectional view of a mask chamber of FIG. 1, according to one embodiment.

FIG. 7 is a side cross-sectional view of one of the processing chambers of the processing system of FIG. 1, according to one embodiment.

FIG. 8 is a flow diagram for the operation of the transfer chamber in FIG. 1 according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the disclosure generally relate to a vacuum processing system for vacuum processing large area substrates (e.g., LCD, OLED, and other types of flat panel displays, solar panels, and the like). Although a vacuum processing system for performing depositions on large area substrates is described herein, the vacuum processing system may alternatively be configured to perform other vacuum processes on substrates, such as etching, ion implantation, annealing, plasma treating, and physical vapor depositions among other processes.

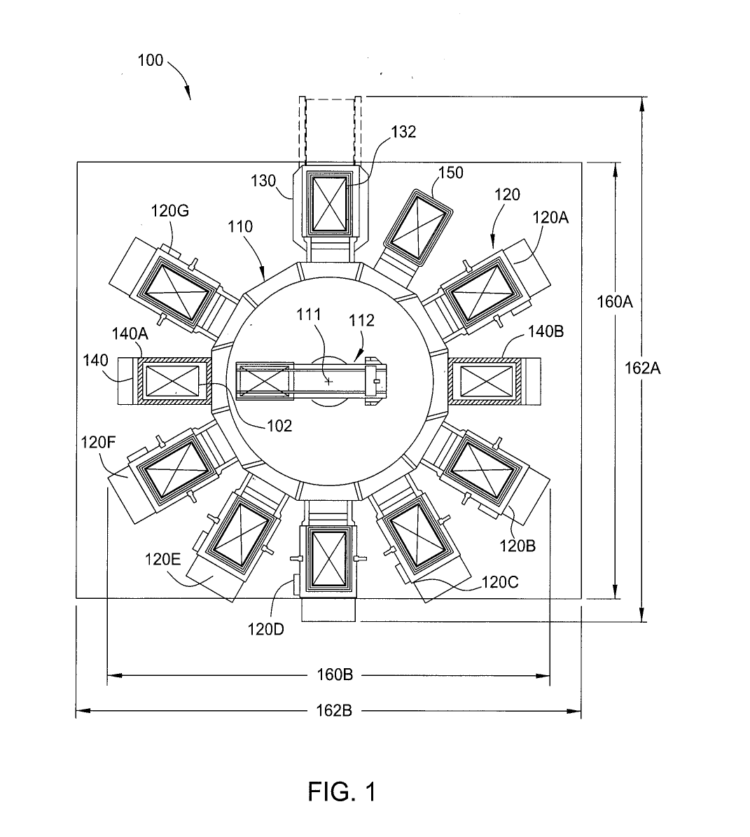

FIG. 1 is a top cross-sectional view of a processing system 100 for performing vacuum processing on a plurality of substrates 102, according to one embodiment of the disclosure. The processing system 100 has a transfer chamber 110. A plurality of processing chambers 120 are coupled to the transfer chamber 110. Additionally, one or more load lock chambers 140 are coupled to the transfer chamber 110. Optionally, one or both of a mask chamber 130 and a buffer chamber 150 may be coupled to the transfer chamber 110. The transfer chamber 110, processing chambers 120, load lock chamber 140, as well as any additionally attached chambers forming the processing system 100, are sealing coupled to maintain a vacuum environment therein.

The processing system 100 is configured to hold and process multiple substrates 102. Each substrate 102 has a length, width, and a thickness. The length of the substrate 102 may be longer than the width, in some embodiments, by 50% or more. For example, in one embodiment each substrate 102 has a length of about 1500 mm and a width of about 925 mm. The thickness of the substrate 102 may be a few millimeters or less, such as about 0.3 millimeters to about 0.5 millimeters thick. The substrate 102 may be comprises of glass, plastic or other material.

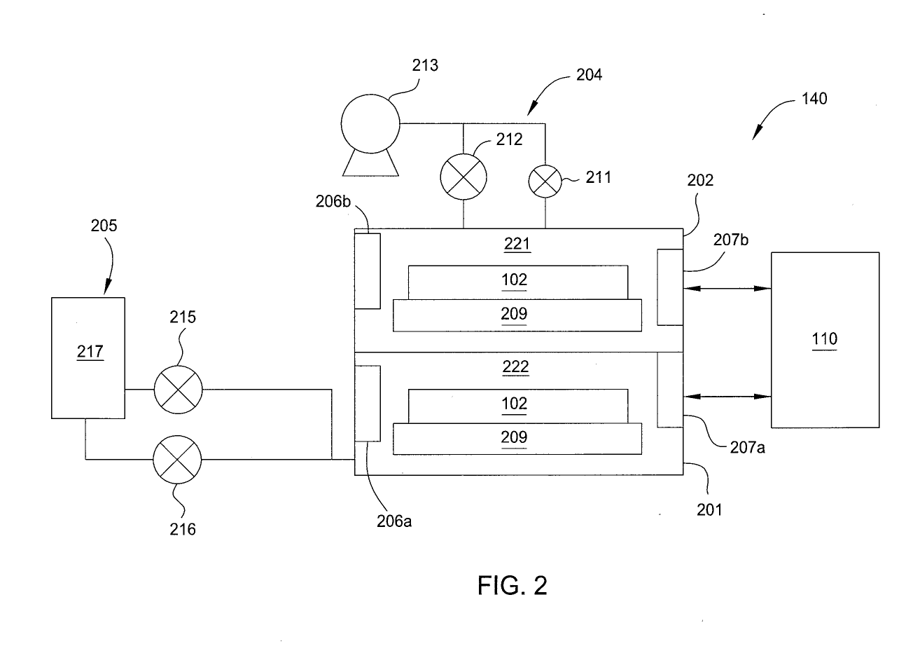

The substrate 102 may be moved into and out of the processing system 100 through the load lock chamber 140. Turning briefly to a schematic view of the load lock chamber 140 illustrated in FIG. 2, the load lock chamber 140 may be a dual single cavity load lock. The load lock chamber 140 includes a first load lock cavity 201 (e.g., a lower load lock substrate receiving cavity) and a second load lock cavity 202 (e.g., an upper load lock substrate receiving cavity) disposed over the first load lock cavity 201. The first load lock cavity 201 has a first interior volume 221. The second load lock cavity 202 has a second interior volume 222. Each interior volume 221, 222 is sized accommodate a substrate therein.

The load lock chamber 140 also optionally included lower and upper exhaust systems 204 coupled respectively to the interior volumes 221, 222 of the first load lock cavity 201 and the second load lock cavity 202. The load lock chamber 140 may optionally include a gas supply system 205 for providing process gases to the first load lock cavity 201 and/or the second load lock cavity 202. Process gases may include, for example, inert gas such argon, or other process-inert gases such as nitrogen.

Each of the first load lock cavity 201 and the second load lock cavity 202 include a substrate support 209 disposed in the interior volume 221, 222 configured to support one or more substrates 102 thereon. The substrate support 209 may additionally be configured to rotate the substrate 102 while in the load lock cavities 201, 202. The substrate support 209 may rotate through at least 90 degrees or even 180 degrees to orientate the substrate 102. The load lock chamber 140 may have a substrate breakage sensor at each corner to monitor the position and condition of the substrate 102. With this arrangement, the load lock chamber 140 may be able to maintain substrate alignment to within 250 micrometers.

Each of the first load lock cavity 201 and the second load lock cavity 202 include a respective door 206a, 206b which may be opened to allow access to the load lock cavities 201, 202 for ingress and egress of a substrate. For example, the doors 206a, 206b may be opened to facilitate transfer of a substrate to/from parts of a fabrication facility through a factory interface (FI, not shown), or other areas that are generally maintained at atmospheric pressure. In one example, the doors 206a may be opened to allow access to the first load lock cavity 201 to facilitate transfer of a substrate from an environment maintained at atmospheric pressure, while the doors 206b of the second load lock cavity 202 may be closed to facilitate transfer of a substrate to the vacuum environment maintained in the transfer chamber 110.

Each of the first load lock cavity 201 and the second load lock cavity 202 also include a respective slit valve 207a, 207b to seal the load lock chamber 140 from the transfer chamber 110. Operation of the slit valves 207a, 207b facilitate transfer of the substrate 102 to/from the transfer chamber 110 in the processing system 100. In one aspect, the slit valves 207a, 207b may be opened to allow transfer of a substrate with the transfer chamber 110 of the processing system 100. For example, the slit valve 207a may be opened to allow access to the first load lock cavity 201 to facilitate transfer of a substrate from the first load lock cavity 201 to the transfer chamber 110 of processing system 100, while the slit valve 207b may be closed to allow access to the second load lock cavity 202 from atmosphere while the door 206b is opened to facilitate transfer of a substrate between the second load lock cavity 202 at a FI or other atmospheric region.

The exhaust system 204 is coupled to the first load lock cavity 201 and the second load lock cavity 202. The exhaust system 204 facilitates removal of gases from the interior volumes of the first load lock cavity 201 and the second load lock cavity 202. The exhaust system 204 may include a pump 213 coupled to the load lock cavities 201, 202 through valves 211, 212. The first interior volume 221 and second interior volume 222 may be pumped down and operate at pressures between about 780 Torr to less than 100 mTorr. The pump 213 may be sufficient to pump down the pressure in the first or second interior volume 221, 222, in less than about 20 seconds, i.e., decrease the pressure from 780 Torr to less than about 100 mTorr. Similarly, the valves 211, 212 may vent and to bring the pressure to back from 100 mTorr to about 780 Torr in 20 seconds or less.

Process gases may be supplied to the first or second load lock cavity 201, 202 via a gas supply system 205. The gas supply system 205 includes first valves 215, 216 which couple a gas supply source 217 to the first or second load lock cavity 201, 202.

In another example, the load lock chamber 140 may include a single load lock cavity, such as the first load lock cavity 201 such that the load lock chamber 140 may handle only a single substrate at a time. In a single substrate cavity configuration, the load lock chamber 140 may function as a pass through for coupling the processing system 100 to an adjoining processing system such that substrates may be transferred between the processing systems without breaking vacuum (i.e., without exposing the substrates to atmospheric pressures).

In yet another example as shown in FIG. 1, the load lock chamber 140A may only have the first load lock cavity 201 such that the load lock chamber 140A may handle only a single substrate at a time, while the load lock chamber 140B may include both the first load lock cavity 201 and the second load lock cavity 202, such that the load lock chamber 140B may handle two substrates simultaneously. Thus, processing system 100 can be configured to transfer substrates between adjacent processing systems through the load lock chamber 140A, while transferring substrates with an atmospheric factory interface through the load lock chamber 140B.

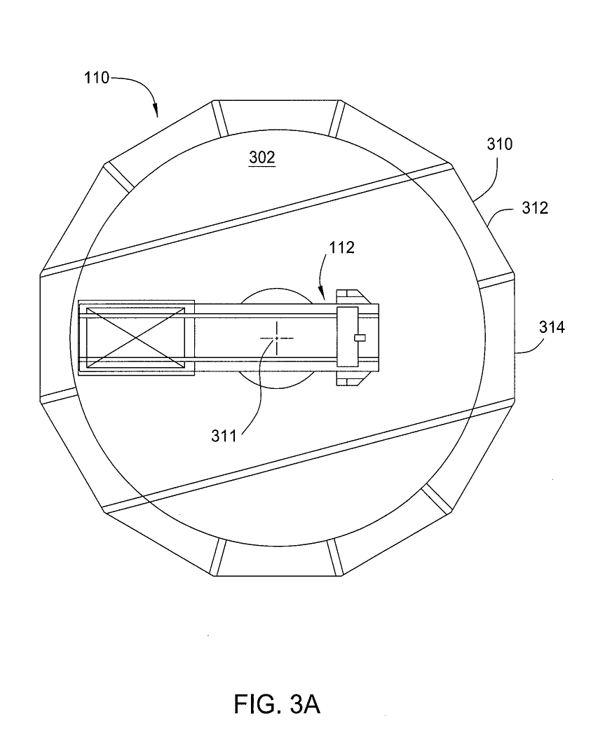

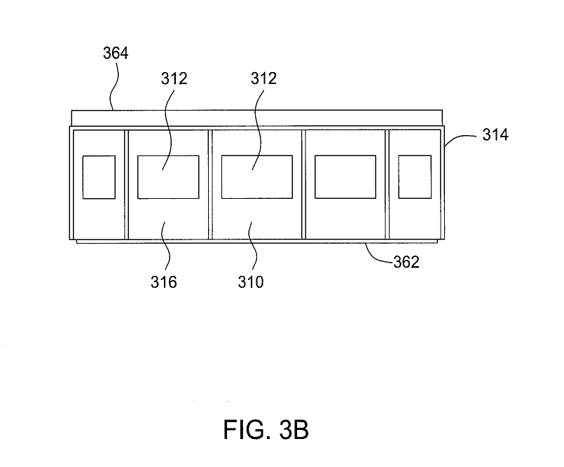

FIG. 3A is a top plan view of the transfer chamber 110 of FIG. 1, according to one embodiment. FIG. 3B is a side plan view of the transfer chamber 110 of FIG. 1. Referring now to FIGS. 1, 3A and 3B, the load lock chamber 140 is coupled at the slit valve 207 to a face 310 of the transfer chamber 110. The transfer chamber 110 has a lid 364 and a bottom surface 362. A plurality of sidewalls 316 sealingly coupling the lid 364 to the bottom surface 362 and define an internal volume 302. The lid 364 may be hinged to the sidewalls 316 and be movable between an open position to expose the internal volume 302 to environment outside the transfer chamber 110 and a closed position forming an airtight seal against the sidewalls 316. The plurality of sidewalls 316 forms the outer perimeter 314 of the transfer chamber 110. As shown in the top plan view of FIG. 3A, the outer perimeter 314 has a polygonal shape, having twelve of the faces 310. The center 111 of the processing system 100 may be coincident with a center 311 of the transfer chamber 110. Alternately, the center 311 is not aligned with the center 111 of the processing system 100.

The faces 310 of the transfer chamber 110 have openings 312 formed through the sidewalls 316. The openings 312 are sized to allow the substrate 102 to pass through the opening 312 and enter the internal volume 302 of the transfer chamber 110. For example, the openings 312 have a horizontal width that is greater than the width of the substrate 102. In one example, the openings 312 have a horizontal width of at least 925 mm. The faces 310 are substantially flat and configured to sealingly engage one of the other chambers (120, 130, 140, 150).

A seal, gasket or other suitable technique may utilized to form a seal around the opening 312 in the face 310 and an abutting processing chamber, such as the load lock chamber 140, mask chamber 130, processing chamber 120, buffer chamber 150 or other chamber. For example, an O-ring (not shown) may be utilized to provide an air tight seal between the load lock chamber 140 and the opening 312 in the face 310 of the transfer chamber 110. The coupling between the load lock chamber 140 and the transfer chamber 110 is made air tight by the seal such that the atmospheric pressure between the interior volume 221, 222 of the load lock chamber 140 can be maintained with the internal volume 302 of the transfer chamber 110 when the slit valve 207 is open to the transfer chamber 110.

The exhaust system 204 is coupled to the transfer chamber 110. The exhaust system 204 removes gases from the internal volume 302 of the transfer chamber 110 for maintaining a vacuum environment therein. The exhaust system 204 is operable to create an atmosphere of between about 10 Torr and about 50 m Torr within the internal volume 302.

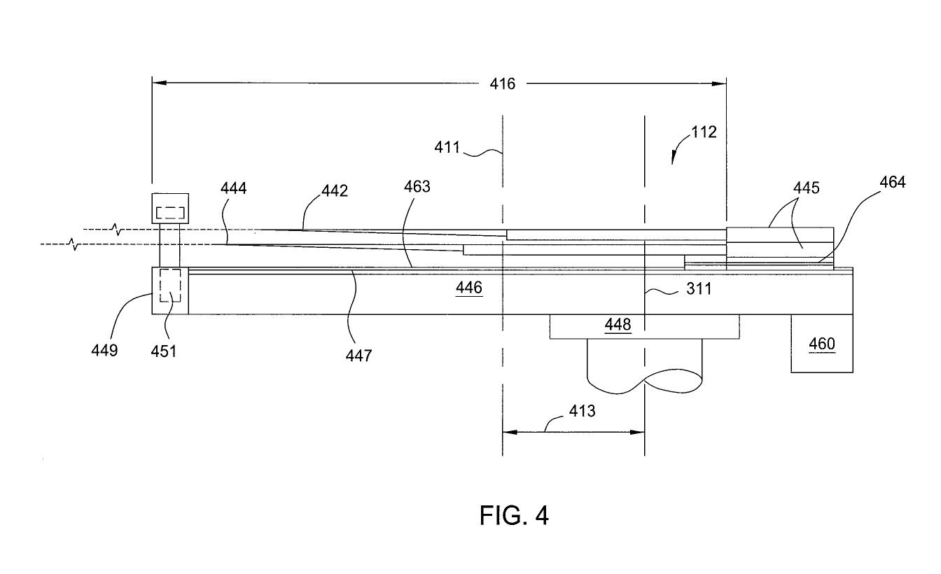

A dual arm vacuum transfer robot 112 is disposed in the internal volume 302 of the transfer chamber 110. The substrate 102 in the load lock chamber 140 may be transferred through the slit valve 207 by the transfer robot 112 into the transfer chamber 110. Turning briefly to FIG. 4, FIG. 4 is a side cross-sectional view of one embodiment of the robot 112 used in the transfer chamber 110 of FIG. 1, according to one embodiment.

The transfer robot 112 is disposed in the transfer chamber 110 and can be used to move the substrates 102 and the masks 132 to and from the chambers that surround the transfer chamber 110, such as the processing chambers 120, the load lock chambers 140, and the mask chamber 130. The transfer robot 112. The transfer robot 112 has a body 446 disposed on a base 448. The transfer robot 112 may optionally have a cooling plate 447. The cooling plate 447 may be attached to a cooling fluid source (not shown) which provides a heat transfer fluid for reducing the amount of heat transferred from the substrate 102 to the transfer robot 112. The body 446 is rotatable on a vertical axis extending through the base 448.

The transfer robot 112 has a wrist 445 attached to a first end effector 442, i.e., upper end effector. The wrist 445 and first end effector 442 may be attached to a guide 464. The guide 464 may move along a rail 463 on the body 446. The wrist 445 and the first end effector 442 are moveable horizontally along the rail 463 and rotate relative to the base 448. The first end effector 442 includes a substrate support surface that is configured to support a substrate 102 while being moved by the transfer robot 112. The wrist 445 and first end effector 442 are movable between a retracted position substantially centered over the body 446, and an extended position that extends the first end effector 442 laterally beyond a forward portion 449 of the body 446 so that the first end effector 442 may be positioned within one of the chambers attached to the transfer chamber 110 for facilitate substrate transfer therewith. The body 446 can rotate to orientate and align the forward portion 449 of the body 446 in the direction of extension of the first end effector 442 with any of the chambers.

In another example, the wrist 445 and first end effector 442 are laterally offset from the center 311 of the transfer chamber 110 such that the wrist 445 is closer to the center 311 relative to the opposite end. Thus, a center of balance 411 for the transfer robot 112 may is offset a distance 413 from the base 448 centered about the center 311 of the transfer chamber 110. Having the first end effector 142 offset from the center 311 allows the first end effector 442 to be extended laterally to facilitate substrate transfer with the other chambers 120, 130, 140, 150 using a shorter and less costly range of motion of the first end effector 442. To balance the weight of the transfer robot 112, when transferring the substrate 102 on the first and/or second end effectors 442, 444, a counter balance weight 460 may be disposed adjacent the wrist 445.

The transfer robot 112 is capable of moving two substrates 102 or two masks 132 at the same time to or from one of the chambers, such as processing chamber 120, which surrounds the transfer chamber 110. The first end effector 442 of the transfer robot 112 can have a length 416 and a width sufficient to support the substrate 102. The length 416 is parallel to the radial direction in which the transfer robot 112 can extend, for example, radially from the center 311 of the transfer chamber 110 into one of the processing chambers 120. The transfer robot 112 may extend a distance of about 5085 millimeters in the horizontal direction and move in a vertical direction about 550 millimeters to move the substrate 102 from one chamber to another. In one embodiment, the first end effector 442 of the transfer robot 112 may extend a distance of about at least 5000 millimeters in a horizontal direction and move a distance of about at least 540 millimeters in a vertical direction. The transfer robot 112 may have a position repeatability of less than 0.5 millimeters to prevent substrate damage and increase throughput. In some embodiments, the transfer robot 112 can include an upper end effector (i.e., the first end effector 442) and a lower end effector (i.e., a second end effector 444) that can allow the transfer robot 112 to move substrates 102 and/or masks 132 independently from each other on the first and second end effectors 442, 444. In some embodiments, the first and second end effectors 442, 444 can be used to move two substrates 102 or two masks 132 simultaneously. When the transfer robot 112 includes first and second end effectors 442, 444, each end effector may be controlled independently by a motor. In one embodiment, the transfer robot 112 is a dual-arm robot having first and second end effectors 442, 444 and a separate motor for each arm. In another embodiment, transfer robot 112 has first and second end effectors 442, 444 coupled through a common linkage. The transfer robot 112 may be sufficiently quick to exchange the substrate 102 between the processing chamber 120 and the load lock chamber 140 in less than about 20 seconds. Additionally, the transfer robot 112 may exchange a mask between the mask chamber 130 and the processing chamber 120 in less than about 40 seconds.

A substrate chip and alignment detector 451 (detector 451) may optionally be attached to the body 446 of the transfer robot 112. The substrate 102, disposed on the first end effector 442, travels past the detector 451 as the first end effector 442 is extends and retracts. As the substrate 102 positioned on the first end effector 442 moves past the sensor in the detector 451, the position of the substrate 102 relative to the first and second end effectors 442, 444, along with defects on the edges of the substrate 102, to be detected.

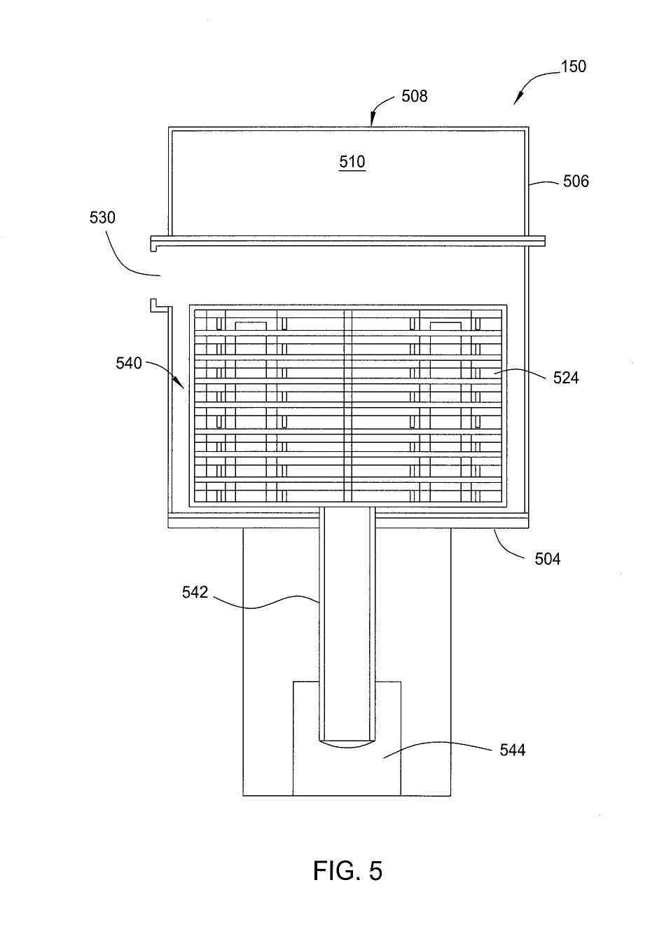

The transfer robot 112 may move substrates 102 in and out of the processing chamber 120 to and from the load lock chamber 140. However, during times where occurrences downstream in the process cause substrates 102 leaving the processing chamber 120 to have nowhere available to go, the substrate 102 may be transferred into the buffer chamber 150. FIG. 5 is a side cross-sectional view of the buffer chamber 150 shown in FIG. 1, according to one embodiment. The buffer chamber 150 is configured to hold substrates 102 while the substrates 102 are waiting to be transferred to another chamber in the processing system 100, or to be transferred out of the processing system 100. For example, a first substrate may be scheduled for processing in a first chamber currently occupied by a second substrate undergoing processing therein. The first substrate may be transferred by the transfer robot 112 to the buffer chamber 150 to free up the transfer robot 112 to move other substrates in and out of other chambers while the first substrate waits for the availability of the first processing chamber.

The buffer chamber 150 may have a lid 508, walls 506 and a floor 504 which define and enclose an interior volume 510. An opening 530 may be formed in the wall 506. The opening 530 is configured for a substrate 102 to pass therethrough. The buffer chamber 150 may optionally have a slit valve or other closing mechanism for the opening 530. The opening 530 is additionally configured to align with one of the openings 312 in the in the face 310 of the transfer chamber 110. A seal, gasket or other suitable technique may utilized to form a seal around the opening 530, such that the buffer chamber 150 may form an air seal with the face 310 of the transfer chamber 110. The interior volume 510 of the buffer chamber 150 may air tight and maintained at a base pressure of less than about 10 mTorr. The buffer chamber 150 may have a vacuum pump for maintaining the pressure therein. Alternately, the pressure in the interior volume 510 may be achieved when the pressure within the buffer chamber 150 is equalized with the pressure within the transfer chamber 110 through the openings 312, 530. Thus, the buffer chamber 150 may have an operational temperature similar to the transfer chamber 110, i.e., between about 50 mTorr and about 100 mTorr.

The buffer chamber may have a support rack 540. The support rack 540 is supported by a shaft 542. The shaft 542 may be attached to a drive unit 544. The drive unit 544, may be a linear motor, mechanical device, hydraulic unit or other suitable movement mechanism capable of moving the shaft 542 vertically between an extended and retracted position for raising and lowering the support rack 540. The support rack 540 may have slots 524. Each slot 524 may be configured to accept the substrate 102 thereon. The support rack 540 may be configured to hold multiple substrates 102 in respective slots 524. For example, the support rack 540 may have six slots 524 for holding six substrates therein within the interior volume 510 of the buffer chamber 150.

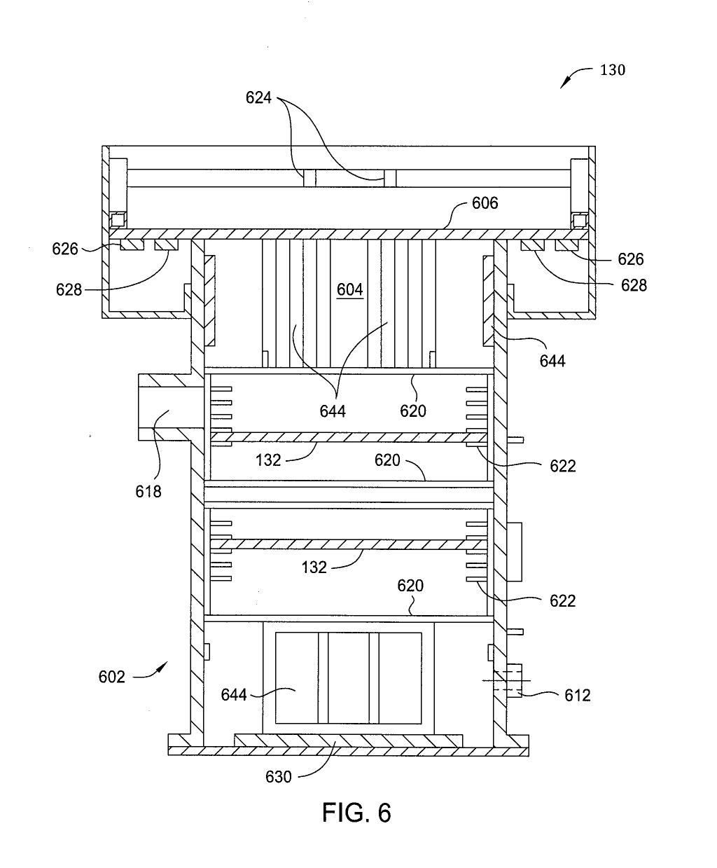

The support rack 540 may be raised or lowered by the drive unit 544 to align the slots 524 with the opening 530 for access by the transfer robot 112. The transfer robot 112 may move a substrate from the slot 524 to the load lock chamber 140 or in some instances the processing chamber 120. The transfer robot 112 may additionally move a mask 132 from the mask chamber 130 to the processing chamber 120 for processing the substrate 102 therein. FIG. 6 is a side cross-sectional view of the mask chamber 130 of FIG. 1, according to one embodiment.

A plurality of masks 132 may be utilized during the processes performed in the processing system 100 as further described below. The mask chamber 130 can be used to store the masks 132 to be used in the processes, such as deposition processes, performed in the different processing chambers 120. For example, the mask chamber 130 may store from about 4 to about 30 masks 132 in one or more cassettes 620. Each mask 132 has a length and a width which can be sized similarly to the length and the width of the substrate 102.

The mask chamber 130 includes a chamber body 602 which defines an inside volume 604. A slit valve 618 may be coupled to the chamber body 602. The slit valve 618 is coupled to the transfer chamber 110 of the processing system 100 and the slit valve 618 is configured to allow for passage of the masks 132 to and from the inside volume 604. The transfer robot 112 is capable of moving the masks 132 on the first end effector 442 into an out of the slit valve 618 in a fashion similar to moving the substrates 102.

A lid member 606 may be coupled to the chamber body 602. The lid member 606 may be configured to enclose the inside volume 604 when the lid member 606 is located in a closed position (as shown). A track member 626 may be coupled to the chamber body 602. A lid actuator 628 may position the lid member 606 in either the open or closed positions. In one embodiment, the lid actuator 628 is an air cylinder. The lid member 606 may translate relative to the chamber body 602 along the track member 626 to open and close access to the inside volume 604. In one embodiment, the lid member 606 may translate along the track member 626 in a first direction and the cassettes 620 may be moved into and out of the inside volume 604.

The inside volume 604 may be sized to receive the cassettes 620 having racks 622 configured to removeably hold the masks 132 therein. The cassettes 620 may be delivered to the mask chamber 130 by a crane or other similar apparatus and positioned within the inside volume 604. One or more alignment actuators 624 may be coupled to chamber body 602. The alignment actuators 624 may be configured to engage a portion of the cassette 620 and assist in positioning the cassette 620 during transfer into the inside volume 604. In one embodiment, the alignment actuators 624 are air cylinders. Used masks 132 that need to be cleaned or conditioned may be removed from the mask chamber 130 by opening the lid member 606 and removing the cassette 620 containing the used masks. New masks 132 may be provided to the mask chamber 130 by a new cassette 620 and the lid member 606 may then be closed.

The mask chamber 130 may be configured to create an environment in the inside volume 604 suitable for conditioning the masks 132, and more specifically, for heating and cooling the masks 132. A pumping apparatus 612 may be coupled to the chamber body 602 and may be configured to generate a vacuum in the volume. In one embodiment, the pumping apparatus 612 is a cryogenic pump. The pumping apparatus 612 may generate a vacuum environment in the volume which may be substantially similar to the environment of the transfer chamber 110 to which the mask chamber 130 is coupled. As such, when the slit valve 618 is opened to receive or discharge one of the masks 132, vacuum may not be broken which may improve the efficiency of mask transfer. In one embodiment, the mask chamber 130 operates at a pressure of about 100 mTorr to about 760 Torr.

Heating members 644 may be coupled to the chamber body 602 within the inside volume 604 and adjacent the cassette 620 and the mask 132. The heating members 644 may be configured to heat the mask 132 and also aid in cooling the mask 132. In one embodiment, the heating members 644 may be reflective heaters or resistive heaters. The heating members 644 may be configured to heat and cool down the masks 132 to a temperature of between about 20 degrees Celsius and about 100 degrees Celsius, such as between about 40 degrees Celsius and about 80 degrees Celsius. Generally, new masks may be heated and used masks may be cooled. A temperature sensor may be coupled to the chamber body 602 and extend into the inside volume 604 and configured to indicate the temperature of the masks 132 disposed therein.

A platform 630, which is coupled to the linear actuators and disposed within the inside volume 604, may be configured to contact the cassettes 620 and translate the cassettes 620 through the inside volume 604. In one embodiment, the platform 630 is configured to translate in the vertical direction a stroke distance of between about 1500 mm and about 2500 mm, such as between about 2200 mm and about 2300 mm. The platform 630 may position the rack 622 in the cassettes 620 relative to the slit valve 618 so that the masks 132 may be removed from or placed into the cassette 620. The transfer robot 112 may move the mask into the processing chamber 120 to process the substrate 102 therein.

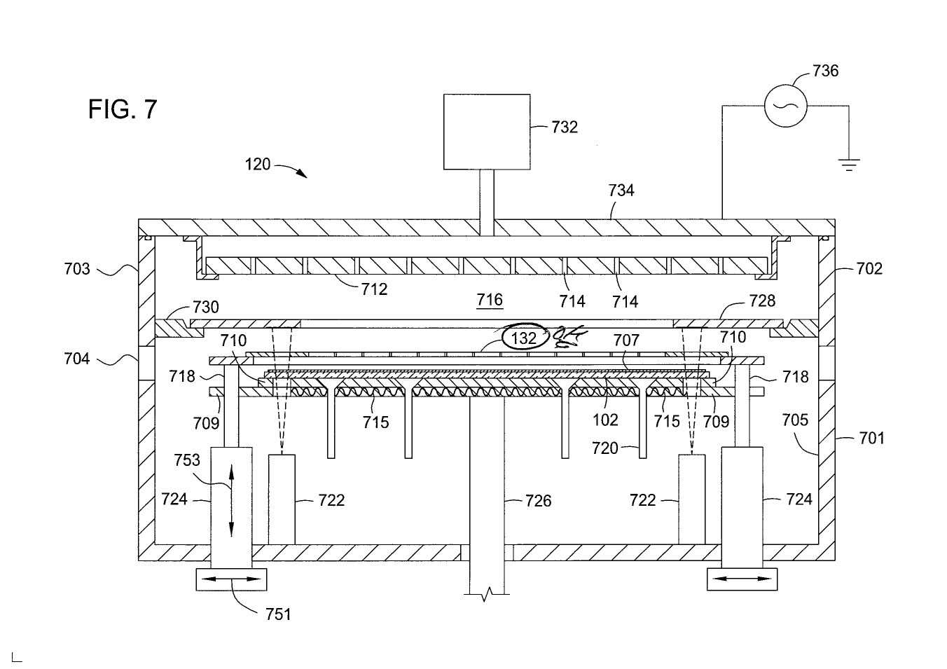

FIG. 7 is a side cross-sectional view of one of the processing chambers 120 of the processing system 100 shown in FIG. 1, according to one embodiment. As illustrated in FIG. 1, there may be multiple processing chambers 120, such as processing chamber 120A through 120F. The processing chambers 120A-120F can each be a chemical vapor deposition (CVD) chamber. Alternately, the processing chambers 120A-120F (collectively processing chambers 120) may each be from a variety of chambers, such as a CVD chamber, a plasma enhanced CVD chamber, an atomic layer deposition chamber (ALD) or other type of deposition chamber. The processing chambers 120 may each accommodate one or more substrates 102 and masks 132 to enable processes, such as a deposition process, to be performed on one or more substrates 102 within each processing chamber 120. In one embodiment, the processing chambers 120 are CVD chambers as described in further detail below.

The processing chamber 120 includes a chamber body 702. The chamber body 702 has sidewalls 701. The sidewalls 701 surround and define a processing space 716 inside the chamber body 702. The sidewalls 701 include a first wall 703 having an opening 704. The opening 704 can be open and closed by the operation of a slit valve or similar equipment. The first wall 703 is generally perpendicular to the direction of extension of the transfer robot 112. The first wall 703 may have an airtight seal against the face 310 of the transfer chamber 110. The opening 704 may align with the opening 312 of the transfer chamber 110 and is configured for transferring substrates 102 and/or masks 132 there through by the transfer robot 112 into the processing space 716 of the processing chamber 120.

A pumping apparatus (not shown), may be coupled to the chamber body 702 and may be configured to generate a vacuum in the processing space 716. In one embodiment, the pumping apparatus is a cryogenic pump. The pumping apparatus may generate a vacuum environment in the processing space 716 which may be substantially similar to the environment of the transfer chamber 110 to which the processing chamber 120 is coupled. As such, when the slit valve is opened to receive or discharge one of the masks 132 or substrates 102, the vacuum is not be broken which may improve the efficiency of the processing chamber 120. In one embodiment, the processing chamber 120 operates at a pressure of about 100 mTorr to about 2 Torr.

The processing chamber 120 includes a substrate support 709 for supporting one or more substrates 102. The substrate support 209 includes a support surface 710 on which a substrate 102 is disposed during processing. The substrate support 709 can include one or more heating elements 715. In one embodiment, the heating elements 715 have heat transfer fluid flowing therethrough. In another embodiment, the heating elements 715 are resistive heaters. In other embodiments, one or more heating elements 715 can configured to provide independent control of the heating of the substrate support 709. For example, the heating elements 715 for the substrate support 709 may be independently controlled and set up into heating zones. The heating elements 715 may heat the substrate support 709 to between about 50 degrees Celsius and about 100 degrees Celsius. The heating elements 715 may be configured to maintain the substrate 102, disposed on the substrate support 209, at a temperature between about 77.5 degrees Celsius and about 82.5 degrees Celsius.

The processing chamber 120 may have additional heaters disposed therein for heating the interior surfaces 705 of the sidewalls 701, a diffuser 712 and the chamber body 702. The diffuser 712 and sidewalls 701 may have channels (not shown) disposed throughout for flowing a heat transfer fluid. Alternately, the diffuser 712 and sidewalls 701 may have resistive or other suitable heaters disposed therein. The heaters may maintain the diffuser 712 at a temperature between about 50 degrees Celsius and about 100 degrees Celsius. Additionally, heaters disposed in the sidewalls 701 may maintain the chamber body 702 of the processing chamber 120 at a temperature of about 120 degrees Celsius plus or minus about 30 degrees Celsius.

The substrate 102, during processing, is disposed on the support surface 710 opposite the diffuser 712. The diffuser 712 includes a plurality of openings 714 to permit processing gas to enter the processing space 716 defined between the diffuser 712 and the substrate 102. Processing gas is delivered from one or more gas sources 732 through an opening formed in a backing plate 734 above the diffuser 712 while an electrical bias can be provided to the diffuser 712 with a radio frequency source 736. The radio frequency source 736 may be coupled through a matchbox (not shown) and generate a variable frequency RF for maintaining the plasma in the processing chamber 120.

For processing, the mask 132 is initially inserted into the processing chamber 120 through the opening 704 in the first wall and is disposed upon multiple motion alignment elements 718. The motion alignment elements 718 have an actuator 724 which is moveable in an x-direction 751 and a y-direction 753 and configured to align the mask 132 in the processing chamber 120 with the substrate 102. The substrate 102 is then also inserted though the opening 704 in the first wall 703 and disposed upon multiple lift pins 720 that can extend through the support surface 710 of the substrate support 709. The substrate support 709 then raises to meet the substrate 102 so that the substrate 102 is disposed on the support surface 710. Once the substrate 102 is disposed on the support surface 710, one or more visualization systems 722 determine whether the mask 132 is properly aligned over the substrate 102. The visualization system 722 may determine alignment of the mask 132 with the substrate 102 to within about ±10 microns. The visualization system 722 may additionally aid alignment of SF loading on the mask to within about ±50 microns. during the loading substrate If the mask 132 is not properly aligned, then one or more actuators 724 of the alignment system move one or more of the motion alignment elements 718 in an x-direction 751 and/or the y-direction 753 to adjust the location of the mask 132. The one or more visualization systems 722 then recheck the alignment of the mask 132. This process of adjusting the position of the mask 132 with the actuators 724 and rechecking the position can be repeated until the mask 132 is properly aligned over the substrate 102.

Once the mask 132 is properly aligned over the substrate 102, the mask 132 is lowered onto the substrate 102, and then the substrate support 709 rises through movement of a connected shaft 726 until the mask 132 contacts an optional shadow frame 728. The shadow frame 728, prior to resting on the mask 132, is disposed in the chamber body 702 on a ledge 730 that extends from one or more interior surfaces 705 of the sidewalls 701 of the chamber body 702. The substrate support 209 continues to rise until the substrate 102, the mask 132 and the shadow frame 728 are disposed in a processing position. One or more layers 707 can then be deposited on the substrates 102 in the processing chamber 120 using the process described above with the mask 132 disposed above each substrate 102. For example, in some embodiments, one or more of the layers 707 may be a silicon containing material, such as silicon nitride, silicon oxide, silicon oxynitride and the like. The one or more layers 707 may be deposited to a thickness of about 5,000 Angstroms to about 10,000 Angstroms thick.

Returning back to FIG. 1, the layout of the processing system 100 is configured to enhance throughput and reduce the system footprint compared to conventional systems. The processing system 100 may have a throughput of about 55 seconds per substrate compared to conventional systems having a throughput of about 60 seconds per substrate.

The processing system 100 may have a length 160B and a width 160A of about 15.40 meters by 12.12 meters respectively. The footprint for the processing system 100 is smaller than most conventional systems having comparable throughput. Advantageously, the processing system 100 occupies about ⅗^{th} of overall floor space with a greater throughput compared to most conventional systems. This has the additional advantage of reducing the size of a crane and the service area. For example, the crane moving cassettes and other equipment may be required to extend over a width 162A and a length 162B of about 12.9 meters and 14.9 meters respectively.

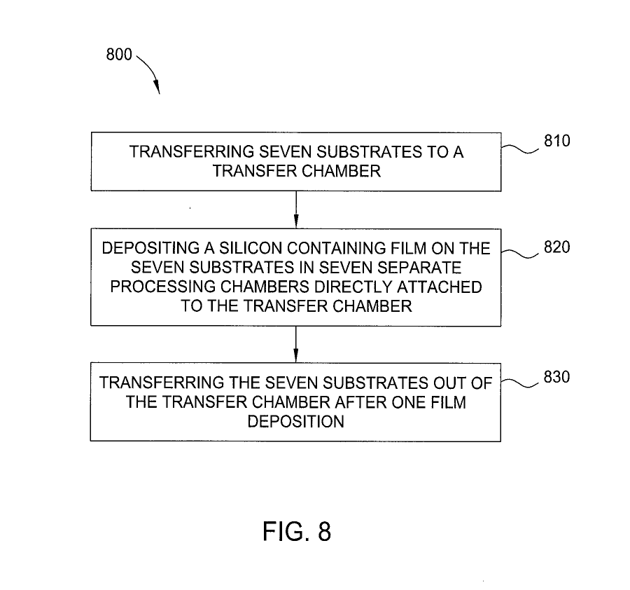

To appreciate the advantages gained in throughput by the configuration for the processing system 100, a sample operation of the processing system will now be discussed with regard to FIG. 8. FIG. 8 is a flow diagram for the operation of the transfer chamber 110 shown in FIG. 1 according to one embodiment.

The method 800 begins at block 810 where seven substrates are transferred into to a transfer chamber. The transfer chamber has twelve sides and a single transfer robot disposed therein. Transferring the substrates is performed by the transfer chamber robot. Each of the twelve sides of the transfer chamber is configured to accept and seal against a chamber such as a processing chamber, buffer chamber, mask chamber or other processing equipment utilized for processing substrates in a vacuum environment. The seven substrates may be transferred through one or more slots in a first load lock chamber. In one embodiment, the first load lock chamber has two slots for supporting substrates and is sealingly attached to one of the sides of the transfer chamber. A first and second substrate is transferred from the load lock chamber by the transfer chamber robot through the transfer chamber. A third and fourth substrate is moved into the first load lock for transfer by the transfer robot. As substrates are moved into the transfer chamber by the transfer robot a next substrate is placed into the queue by being moved into the first load lock chamber.

The substrates are moved into processing chambers attached to the transfer chamber by the transfer robot. The transfer chamber has twelve sides along a periphery allowing for 12 chambers to be sealingly attached thereto. The transfer chamber may have one or more load lock chamber and a plurality of processing chambers. In one embodiment, the transfer chamber has seven or more processing chambers attached thereto. The transfer chamber may additionally have a mask chamber for holding a plurality of masks used in the processing chambers. The masks may be moved to each respective processing chamber for processing the substrate therein. For example, a mask from the mask chamber directly attached to the transfer chamber may be transferred to one of the processing chambers. Optionally, the transfer chamber may have a buffer chamber for holding substrates waiting in the que to be moved through the transfer chamber.

At block 820 a silicon containing film is deposited on the seven substrates in seven separate processing chambers directly attached to the transfer chamber. Each of the substrates is moved into a respective processing chamber. Alternately, two substrates may be moved into a single processing chamber allowing for fourteen (14) substrates to be processed simultaneously. The silicon containing film may be one of SiO₂, SiON, or SiN, among others.

At block 830 the seven substrates are transferred out of the transfer chamber after having a single film deposition performed in one of the processing chambers. Alternately, the substrates may be transferred to a buffer chamber prior to transferring out of the transfer chamber. The buffer chamber may allow processing to continue without having to wait or park a substrate in one of the processing chambers. As each substrate is moved from the processing chamber, a new substrate is placed therein. In one embodiment, the robot has two end effectors and a first end effector removes a substrate from a processing chamber while a second end effector places a substrate therein for processing. This minimizes robot movement and thus increases throughput of the processing system. The substrates may be moved to the first load lock chamber or a second load lock chamber for removal from the processing system

The processing system described above allows for processes to be performed on a large number of substrates while only using a relatively small footprint. The plurality of processing chambers attached to a single transfer chamber advantageously provides minimal handling times for the substrates while allowing multiple substrates to be processed in parallel generating a higher throughput for processed substrates. The higher throughput, along with the smaller footprint reduces operational costs for the system and the overall cost of fabrication.

While the foregoing is directed to embodiments of the present disclosure, other and further embodiments of the disclosure may be devised without departing from the basic scope thereof, and the scope thereof is determined by the claims that follow.

1. A transfer chamber comprising:
a lid;
a bottom disposed opposite the lid;
a plurality of sidewalls sealingly coupling the lid to the bottom and defining an internal volume, wherein the plurality of sidewalls include twelve faces configured to couple to another chamber, each face having an opening formed therethrough that is configured to allow a substrate to pass therethrough;
a base center extending from the lid to bottom within the internal volume, the center being equidistant from the plurality of sidewalls; and
a transfer robot disposed in the internal volume having a center of balance offset a distance from the base center of the transfer chamber, the transfer robot comprising:
a wrist;
at least one effector opposite the wrist, the end effector configured to transfer substrates through the openings; and
a counter balance disposed adjacent the wrist configured to balance the weight of the transfer robot when transferring substrates.

2. The transfer chamber of claim 1, wherein the transfer robot has an upper end effector and a lower end effector, each end effector configured to support a substrate thereon.

3. The transfer chamber of claim 2, wherein end effector of the transfer robot may extend a distance of about at least 5000 millimeters in a horizontal direction and move a distance of about at least 540 millimeters in a vertical direction.

4. The transfer chamber of claim 1 further comprising:
a vacuum pump fluidly coupled to the internal volume, wherein the vacuum pump is operable to create an atmosphere of between about 10 Torr and about 50 mTorr within the internal volume.

5. The transfer chamber of claim 1, wherein the transfer robot comprises:
an upper end effector and a lower end effector, each end effector configured to support a substrate thereon, and wherein the upper and lower end effectors of the transfer robot may extend a distance of about at least 5000 millimeters in a horizontal direction and move a distance of about at least 540 millimeters in a vertical direction.

6. The transfer chamber of claim 1, wherein the opening of each face has a width larger than 925 mm.

7. A processing system for processing a plurality of substrates comprising:
a transfer chamber comprising:
a lid;
a bottom disposed opposite the lid;
a plurality of sidewalls sealingly coupling the lid to the bottom and defining an internal volume, wherein the plurality of sidewalls include twelve faces configured to couple to another chamber, each face having an opening formed therethrough that is configured to allow a substrate to pass therethrough;
a base center extending from the lid to bottom within the internal volume, the center being equidistant from the plurality of sidewalls; and
a transfer robot disposed in the internal volume having a center of balance offset a distance from the base center of the transfer chamber, the transfer robot having comprising:
a wrist;
at least one effector opposite the wrist, the end effector configured to transfer substrates through the openings; and
a counter balance disposed adjacent the wrist configured to balance the weight of the transfer robot when transferring substrates;
a first load lock chamber coupled to one of the faces of the transfer chamber and having an opening, wherein the opening of the first load lock chamber is aligned with one of the openings of the transfer chamber to allow substrate transfer between the first load lock chamber and the transfer chamber;
a buffer chamber coupled to one of the faces of the transfer chamber and having a support rack with a plurality of slots, the buffer chamber configured to hold 5 or more substrates in a vacuum environment on the support rack, the buffer chamber having an opening aligned with one of the openings of the transfer chamber, wherein the support rack is only accessible by the substrates through the opening in the buffer chamber;
a mask chamber coupled to one of the faces of the transfer chamber and having an opening, wherein the opening of the mask chamber is aligned with one of the openings of the transfer chamber to allow mask transfer between the mask chamber and the transfer chamber; and
a plurality of processing chambers coupled to one of the faces of the transfer chamber, each of the processing chambers having an opening aligned with one of the openings in the transfer chamber to allow substrate and mask transfer between the processing chambers and the transfer chamber.

8. (canceled)

9. The processing system of claim 7, wherein the transfer robot has an upper end effector and a lower end effector for supporting separate substrates.

10. The processing system of claim 9, wherein the transfer robot is configured to horizontally move a substrate at least about 5000 millimeters and vertically move a substrate at least about 540 millimeters.

11. The processing system of claim 7 further comprising:
a vacuum pump fluidly coupled to the internal volume of the transfer chamber, wherein the vacuum pump is operable to create an atmosphere of between about 10 Torr and about 50 mTorr within the internal volume.

12. The processing system of claim 7 further comprising:
a second load lock chamber coupled to one of the faces of the transfer chamber and having an opening, wherein the opening of the second load lock chamber is aligned with one of the openings of the transfer chamber to allow substrate transfer between the second load lock chamber and the transfer chamber.

13. The processing system of claim 12, wherein the second load lock chamber is configured with two substrate receiving cavities and wherein the first load lock chamber is configured with a single substrate receiving cavity.

14. The processing system of claim 7, wherein the openings formed through each face has a width larger than about 925 mm.

15. The processing system of claim 7, wherein the plurality of processing chambers are configured to deposit a silicon containing film selected from the group consisting of SiO₂, SiON, and SiN.

16. A method of processing a plurality of substrates comprising:
transferring seven substrates to a transfer chamber of a processing system wherein the transfer chamber has sidewalls with twelve faces configured for attaching chambers thereto;
depositing a silicon containing film on the seven substrates in seven separate processing chambers directly attached to the transfer chamber; and
transferring the seven substrates into a load lock chamber coupled to the transfer chamber after depositing only the silicon containing film deposition.

17. The method of claim 16, wherein the silicon containing film is one of SiO₂, SiON, or SiN.

18. The method of claim 16 further comprising:
transferring one or more of the seven substrates to a buffer chamber.

19. The method of claim 16 further comprising:
transferring a mask from a mask chamber directly attached to the transfer chamber to one or more of the processing chambers.

20. The method of claim 19, wherein transferring the mask further comprises:
transferring the mask and substrates on a common transfer chamber robot disposed in the transfer chamber.
